(19) United States
(12) Patent Application Publication
(10) Pub. No.: US 2003/0148591 A1
(43) Pub. Date: Aug. 7, 2003

(54) Method of forming semiconductor device

(76) Inventors: Jan-Dar Guo, Hsinchu (TW); Tsung-Yu Chen, Keelung (TW); Hui-wen Chuang, Taipei (TW); Jian-Shihn Tsang, Taipei (TW); Wen-Chung Tsai, Hsinchu (TW); Shih-Hsiung Chan, Pingtung (TW)

Correspondence Address: PERKINS COIE LLP, PATENT-SEA, P.O. BOX 1247, SEATTLE, WA, 98111-1247, US

(21) Appl. No.: 10/226,572

(22) Filed: Aug. 23, 2002

(30) Foreign Application Priority Data
Feb. 7, 2002 (TW) 91102285

(51) Int. Cl. H01L 21/30; H01L 21/46

(52) U.S. Cl. 438/455

(57) ABSTRACT

The present invention includes step of selecting a provisional substrate, and forming semiconductor device structure is formed on the provisional substrate. The provisional substrate includes conductor material, semiconductor material or insulator material. Then, next step is to separate the chips on the provisional substrate into a plurality of individual units on the provisional substrate. The separating method includes but is not limited to physical method such as cutting by knife or laser or, chemical method such as lithography. Next step is to select a permanence substrate to attach the device to the permanence substrate by using physical or chemical method. The attaching method includes the usage of glue, metal, fusion, pressure, van der waale force, and so on. Subsequently, the provisional substrate on the other side of the semiconductor device is removed. The method of removing the provisional substrate includes but is not limited to physical polish, chemical etching, or laser removal. The subsequent steps include the step of completing the device manufacture, dicing the permanence substrate, thereby finishing the whole process.

### CROSS-REFERENCE TO RELATED APPLICATION(S)

This application claims the benefit of Taiwan Patent Application No. 91102285, filed Feb. 7, 2002, which is hereby incorporated by reference in its entirety.

1. Technical Field

The present invention relates to a method of making an electronic device, and more specifically, to a method of previously separating chips when manufacturing the device.

1. Background

The large integration of semiconductor ICs has been accomplished by a reduction in individual device size. With this reduction of device size, many challenges arise in the manufacture of the ICs. Each device requires interconnections for exchanging electrical signals from one device to another device. Specially, the high performance integrated circuits have multi-level connections separated by dielectric layers. The technology of forming effective contact has met obstacles due to the device is miniaturized to sub-micron range. One of the approaches for manufacturing the device is to integrate several processes.

The optical-electronic device includes LED, semiconductor laser, solar battery cells, photo detector, and so on. The electronic devices include transistor, mono-polar, bipolar device, diode, microwave device, etc. Under the consideration of simplifying the processes and the reduction of the cost, there is a need to develop a process that is suitable for various of process.

### SUMMARY

An object of the present invention is to provide a method of forming semiconductor device and the structure of the same.

A further object of the present invention is to provide a method of forming semiconductor device including a step of separating the chips previously.

The present invention includes step of selecting a provisional substrate, semiconductor device structure is formed on the provisional substrate. The provisional substrate includes conductor material, semiconductor material or insulator material. Then, next step is to separate the dice on the provisional substrate into a plurality of individual units on the provisional substrate. The separating method includes but is not limited to physical method such as cutting by knife or laser, or chemical method such as plasma etching, photo enhance etching or wet chemical etching. Next step is to select a permanence substrate to attach the device on the permanence substrate by using physical or chemical method. The attaching method includes the usage of glue, metal, fusion, pressure, van der waale force, and so on. Subsequently, the provisional substrate on the other side of the semiconductor device is removed. The method of removing the provisional substrate includes but is not limited to physical polish, chemical etching, or laser removal. The subsequent steps include the step of completing the device manufacture, dicing the permanence substrate, thereby finishing the whole process.

### BRIEF DESCRIPTION OF THE DRAWINGS

FIG. 1 is a diagram of the process according to the present invention.

FIG. 2 is an embodiment according to the present invention.

FIG. 3 is a second embodiment according to the present invention.

FIG. 4 is a third embodiment according to the present invention.

FIG. 5 is a fourth embodiment according to the present invention.

### DETAILED DESCRIPTION

The present invention discloses a method for making a semiconductor device. The process is suitable for making the semiconductor device including optical device and electronic devices. The optical-electronic device includes LED, semiconductor laser, solar battery cells, photo detector, and so on. The electronic device includes transistor, mono-polar, bipolar device, diode, microwave device, etc. The present invention may simplify the processes and reduce the cost.

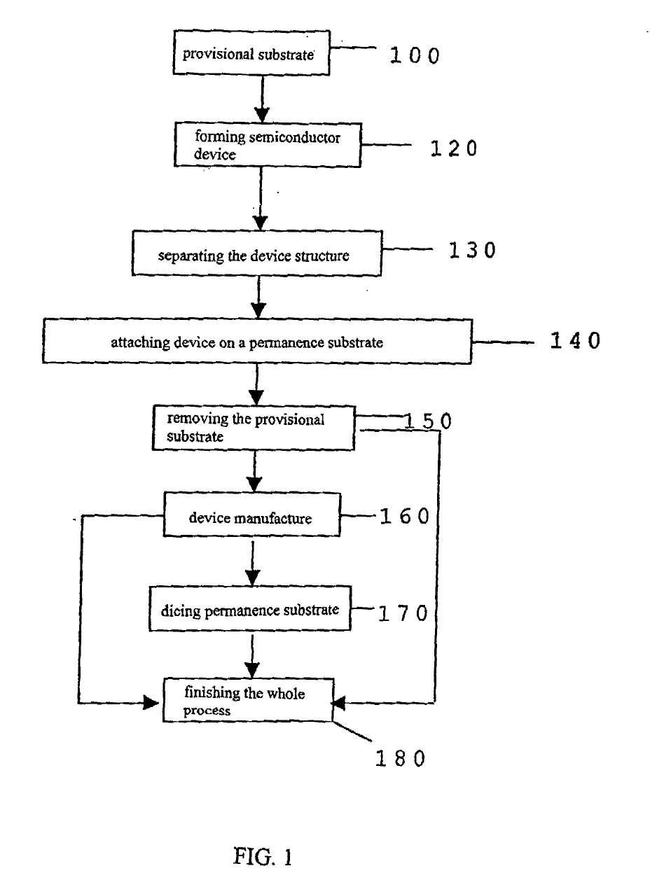

Turning to FIG. 1 and FIG. 2, the steps include step 100, selecting a provisional substrate 2, semiconductor device structure 4 (120) is formed on the provisional substrate 2. The provisional substrate 2 includes conductor material, semiconductor material or insulator material. Then, step 130 is to separate the chips on the provisional substrate 2 into a plurality of individual units on the provisional substrate 2. The separating method includes but is not limited to physical method such as cutting by knife or laser, or chemical method such as plasma etching, photo enhance etching or wet chemical etching. Next step 140 is to select a permanence substrate 6 to attach to the semiconductor device structure 4 on the permanence provisional substrate 2 by using physical or chemical method. The attaching method includes the usage of glue, metal, fusion, pressure, van der waale force, and so on. Subsequently, the provisional substrate 2 on the other side of the semiconductor device structure 4 is removed.

The method of removing the provisional substrate 2 includes but not limited to physical polish, chemical etching, or laser removal. The subsequent steps include the step 160 of completing the device manufacture, dicing the permanence substrate 6, step 170, thereby finishing the whole process 180. The step of dicing the permanence substrate 6 is optional.

FIGS. 2 to 5 are the embodiments of the present invention. The method of FIG. 2 includes:

(A) selecting a provisional substrate 2 and forming semiconductor device structure 4 on the provisional substrate 2;

(B) separating the semiconductor device structure 4 into a plurality of individual units by using physical or chemical method;

(C) selecting a permanence substrate 6 to attach to the other side of semiconductor device structure 4 by using physical or chemical method;

(D) removing the provisional substrate 2 attached to another side of the semiconductor device structure 4, then the device 4 is on the permanence substrate 6.

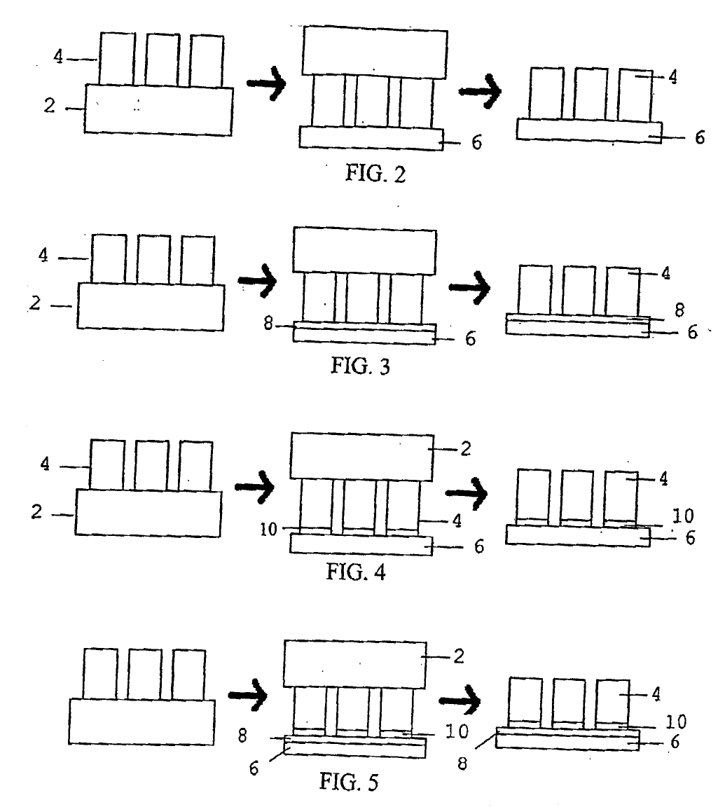

Further method can be seen in FIG. 3 that includes:

(A) selecting a provisional substrate 2 and forming semiconductor device structure 4 on the provisional substrate 2;

(B) separating the semiconductor device structure 4 into a plurality of individual units by using physical or chemical method;

(C) selecting a permanence substrate 6 having layer 8 formed thereon;

(D) then attaching the semiconductor device on the permanence substrate 6 by using physical or chemical method;

(E) removing the provisional substrate 2 attached to another side of the semiconductor device structure 4, and then the device 4 is on the permanence substrate 6.

FIG. 4 illustrates a step of performing semiconductor process on the semiconductor device structure 4, and the number 10 indicates the formed layer.

FIG. 5 illustrates a step of performing semiconductor process both on the semiconductor device structure 4 and the permanence substrate 6. The layers are respectively presented by the number 10 and 8.

The provisional substrate 2 is selected from conductor, semiconductor, insulator material or the combination thereof. The permanence substrate 6 is selected from conductor, semiconductor, insulator material or the combination thereof. The conductor material is selected from metal having single or multiply layers, substrate having coated single or multiply metal layers, alloy substrate or substrate having alloy layers. The semiconductor material is selected from the group of Si, Ge, SiNₓ, SiC, silicide, AIN, GaN, GaAs, GaAs, InP and so on. The insulating material includes SiO₂, Al₂O₃, glass and quartz.

The separating method includes but is not limited to the usage of rigid knife, mechanical dicing, chemical etching, and lithography process. The attaching method includes but is not limited to the usage of glue, metal, fusion, pressure, van der waale force, and so on. The glue includes compound, polymer, and at least one metal glue layer.

The method of removing the provisional substrate 2 includes but is not limited to physical polish, chemical etching, or laser removal.

The benefit of the present invention includes:

1. Simplifying the manufacture, increasing the yield and reducing the cost.

2. We may select the suitable permanence substrate 6 according to the device and process to improve the characteristic of the device.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

Thus, while the preferred embodiment of the invention has been illustrated and described, it will be appreciated that various changes can be made therein without departing from the spirit and scope of the invention.

I/We claim:

1. A method of making semiconductor device comprising:
selecting a provisional substrate and forming semiconductor device structure on said provisional substrate;
separating said device structure into a plurality of individual units by using physical or chemical method;
selecting a permanence substrate, then attaching said semiconductor device to said permanence substrate by using physical or chemical method;
removing said provisional substrate attached to another side of said semiconductor device, and then said device is formed on said permanence substrate.

2. The method of claim 1, wherein said provisional substrate is selected from conductor, semiconductor, insulator, or the combination thereof.

3. The method of claim 2, wherein said conductor is selected from metal having single or multiply layers, substrate having coated single or multiply metal layers, alloy substrate, or substrate having alloy layers.

4. The method of claim 2, wherein said semiconductor material is selected form the group of Si, Ge, SiNₓ, SiC, silicide, AIN, GaN, GaAs, GaAs, InP, and so on.

5. The method of claim 2, wherein said insulating material includes SiO₂, Al₂, O₃, glass, and quartz.

6. The method of claim 1, wherein said permanence substrate is selected from conductor, semiconductor, insulator, or the combination thereof.

7. The method of claim 6, wherein said conductor is selected from metal having single or multiply layers, substrate having coated single or multiply metal layers, alloy substrate, or substrate having alloy layers.

8. The method of claim 6, wherein said semiconductor material is selected form the group of Si, Ge, SiNₓ, SiC, silicide, AlN, GaN, GaAs, GaAs, InP, and so on.

9. The method of claim 6, wherein said insulating material includes SiO₂, Al₂O₃, glass, and quartz.

10. The method of claim 1, wherein said separating includes the usage of rigid knife, mechanical dicing, chemical etching, or lithography process.

11. The method of claim 1, wherein said attaching includes the usage of glue, metal, fusion, pressure, van der waale force, and so on.

12. The method of claim 11, wherein said glue includes compound, polymer, or at least one metal glue layer.

13. The method of claim 1, wherein the removing of said provisional substrate includes but is not limited to physical polish, chemical etching, or laser removal.

14. The method of claim 1, further comprising a step of performing the semiconductor process on said permanence substrate after removing said provisional substrate.

15. The method of claim 1, further comprising a step of performing the semiconductor process after separating said device structure.

16. The method of claim 1, further comprising:
performing the semiconductor process after separating said device structure; and
performing the semiconductor process on said permanence substrate after removing said provisional substrate.
